(19) United States
(12) Patent Application Publication
(10) Pub. No.: US 2025/0220353 A1
(43) Pub. Date: Jul. 3, 2025

(54) MEMS MICROPHONE AND ELECTRONIC DEVICE

(71) Applicant: Goertek Microelectronics Inc., Qingdao, Shandong (CN)

(72) Inventor: Quanbo Zou, Shandong (CN)

(73) Assignee: Goertek Microelectronics Inc., Qingdao, Shandong (CN)

(21) Appl. No.: 18/853,014

(22) PCT Filed: Dec. 16, 2022
(86) PCT No.: PCT/CN2022/139536

§ 371 Date: Sep. 30, 2024

(30) Foreign Application Priority Data
Mar. 31, 2022 (CN) 202210343062.7

(51) Int. Cl. H04R 7/18; B81B 3/00; H04R 7/06; H04R 19/04

(52) U.S. Cl. CPC H04R 7/18; B81B 3/007; H04R 7/06; H04R 19/04; B81B 2201/0257; B81B 2203/0127; H04R 2201/003

(57) ABSTRACT

Disclosed are a MEMS microphone and an electronic device. The MEMS microphone comprises a substrate, a diaphragm, and a backplate. The diaphragm has a fixed part and a suspended part, and the backplate is formed with a support thereon, which divides the suspended part into an inner suspended region and an outer suspended region.

### CROSS-REFERENCE TO RELATED APPLICATIONS

The present disclosure is a National Stage of International Application No. PCT/CN2022/139536 filed on Dec. 16, 2022, which claims priority to a Chinese patent application No. 202210343062.7 filed with the CNIPA on Mar. 31, 2022 and entitled “MEMS MICROPHONE AND ELECTRONIC DEVICE”, both of which are hereby incorporated by reference in their entireties.

### TECHNICAL FIELD

The present disclosure relates to a MEMS (Micro-Electro-Mechanical System) microphone and an electronic device.

### BACKGROUND

In the related art, since the free diaphragm has a large amplitude of movement at the supporting point and the free diaphragm itself has no internal stress, its resonance frequency is low. Therefore, on the premise that the diaphragm has a determined thickness, the area of the free diaphragm is limited by the frequency response bandwidth of the diaphragm and is not easy to be enlarged, and accordingly, its produces considerable acoustic noise, which makes it difficult to meet the demands of electronic products both on the resonant frequency and high signal-to-noise ratio of the microphone.

Therefore, it is necessary to improve application of free diaphragm in MEMS microphones.

### SUMMARY

An objective of the present disclosure is to provide a new type of MEMS microphone and electronic device.

According to an aspect of the present disclosure, a MEMS (Micro-Electro-Mechanical System) microphone is provided, comprising:
a substrate, on which an acoustic cavity is formed;
a diaphragm having a fixed part which is fixed on the substrate, and a suspended part which is located above the acoustic cavity;
a backplate provided on the substrate, forming a gap with the diaphragm and provided with a support distributed annularly thereon, the support extending toward the diaphragm, corresponding to a position of the suspended part and dividing the suspended part into an inner suspended region and an outer suspended region, and the inner suspended region having a mechanical sensitivity and a critical voltage that are correspondingly matched to those of the outer suspended region;
when the backplate and/or the diaphragm is energized, the suspended part is configured for being able to abut against the support such that both the inner suspended region and the outer suspended region are capable of being excited by sound pressure to vibrate.

Optionally, a difference between a mechanical sensitivity of the inner suspended region and that of the outer suspended region is less than or equal to 15%; and

a difference between a critical voltage of the inner suspended region and that of the outer suspended region is less than or equal to 15%.

Optionally, the support is a continuous annular structure; or

the support comprises a plurality of protrusions distributed at intervals.

Optionally, the support comprises a plurality of protrusions, which are centrally symmetrically distributed with respect to a center of the suspended part.

Optionally, the inner suspended region and the outer suspended region of the suspended part have a radial dimension ratio ranging from 0.6 to 0.8.

Optionally, the inner suspended region and the outer suspended region are circular in shape with a radial dimension being a diameter.

Optionally, the inner suspended region has a diameter ranging from 450 μm to 750 μm;

the outer suspended region has a diameter ranging from 650 μm to 1100 μm: and

the diaphragm has a thickness ranging from 0.75 μm to 1.25 μm.

Optionally, the inner suspended region has a diameter of 500 μm;

the outer suspended region has a diameter of 750 μm; and

the diaphragm has a thickness of 1 μm.

Optionally, the support is formed with a reinforcing layer thereon.

Optionally, the reinforcing layer is polycrystalline silicon.

Optionally, when the backplate and/or the diaphragm is energized, the suspended part is spaced apart from the substrate by at least 2 μm in a vibration direction of the suspended part.

According to another aspect of the present disclosure, a MEMS microphone is further provided, comprising:
a substrate, on which an acoustic cavity is formed;
a diaphragm provided on the substrate and located above the acoustic cavity;
a backplate provided on the substrate and forming a gap with the diaphragm;
a support provided on the substrate and/or the backplate, the support being configured for supporting the diaphragm to divide the diaphragm into an inner suspended region and an outer suspended region, and the inner suspended region having a mechanical sensitivity and a critical voltage that are correspondingly matched to those of the outer suspended region.

According to yet another aspect of the present disclosure, an electronic device is provided. The electronic device comprises the above MEMS microphone, and the MEMS microphone is configured for converting, in operation, a sound signal into an electrical signal.

A technical effect of the embodiment of the present disclosure is that by creatively providing the support to divide the diaphragm into the inner suspended region and the outer suspended region so as to improve the relative hardness of the inner suspended region located inside the support, it is thus possible to increase area of the diaphragm while ensuring frequency bandwidth of the product, reduce noise, and improve the signal-to-noise ratio, thus enhancing the overall performance of the microphone product.

Other features and advantages of the present disclosure will become apparent from the following detailed description of exemplary embodiments of the present disclosure with reference to the accompanying drawings.

### BRIEF DESCRIPTION OF THE DRAWINGS

The accompanying drawings, which constitute a part of the description, illustrate embodiments of the present disclosure and, together with the description thereof, serve to explain the principles of the present disclosure.

FIG. 1 is a simplified structural diagram of a MEMS microphone according to an embodiment of the present disclosure;

FIG. 2 is a top view of a MEMS microphone according to an embodiment of the present disclosure;

FIG. 3 is a top view of a MEMS microphone including two supports according to an embodiment of the present disclosure;

FIG. 4 is a schematic structural diagram of a MEMS microphone according to an embodiment of the present disclosure.

### DESCRIPTION OF REFERENCE SIGNS

1. substrate: 2. diaphragm; 3. backplate; 31. support; 001. acoustic cavity; 21. fixed part; 22. suspended part; 221. inner suspended region; 222. outer suspended region; 311. protrusion; 312. reinforcing layer; 4. welding point; H. distance between the substrate and the diaphragm.

### DETAILED DESCRIPTION

Various exemplary embodiments of the present disclosure will now be described in detail with reference to the accompanying drawings. It is to be noted that unless otherwise specified, the scope of present disclosure is not limited to relative arrangements, numerical representations and values of components and steps as illustrated in the embodiments.

Description to at least one exemplary embodiment is for illustrative purpose only, and in no way implies any restriction on the present disclosure or application or use thereof.

Techniques, methods and devices known to those skilled in the prior art may not be discussed in detail; however, such techniques, methods and devices shall be regarded as part of the description where appropriate.

In all the examples illustrated and discussed herein, any specific value shall be interpreted as illustrative rather than restrictive. Different values may be available for alternative examples of the exemplary embodiments.

It is to be noted that similar reference numbers and alphabetical letters represent similar items in the accompanying drawings. In the case that a certain item is identified in a drawing, further reference thereof may be omitted in the subsequent drawings.

The present disclosure provides a MEMS microphone. The MEMS microphone is a microphone manufactured using MEMS technology. Simply put, the MEMS microphone utilize semiconductor material to form capacitors and integrate these capacitors onto micro silicon wafers. The MEMS microphone formed through the MEMS process is characterized by its small size and high sensitivity, and also possesses excellent radio frequency interference (RFI) and electromagnetic interference (EMI) suppression capabilities. The MEMS microphone is commonly used in mid-to-high-end smartphones and other electronic devices.

The MEMS microphone provided by the present disclosure comprises: a substrate 1, a diaphragm 2 an a backplate 3. Wherein, an acoustic cavity 001 is formed on the substrate 1. The diaphragm 2 has a fixed part 21 which is fixed on the substrate 1, and a suspended part 22 which is located above the acoustic cavity 001. The backplate 3 is provided on the substrate 1, forms a gap with the diaphragm 2, and is provided with a support 31 distributed annularly thereon. The support 31 extends toward the diaphragm 2, corresponds to a position of the suspended part 22, and divides the suspended part 22 into an inner suspended region 221 and an outer suspended region 222.

The inner suspended region 221 and the outer suspended region 222 have correspondingly matched mechanical sensitivities Sm and critical voltages Vp. That is, the mechanical sensitivity Sm of the inner suspended region 221 and that of the outer suspended region 222 is substantially identical, and the critical voltage Vp of the inner suspended region 221 and that of the outer suspended region 222 is substantially identical. Through this design, the inner suspended region 221 and the outer suspended region 222 may show similar or identical acoustic performance, and better realize the sound reception function.

When the backplate 3 and/or the diaphragm 2 is energized, the suspended part 22 is configured for being able to abut against the support 31 such that both the inner suspended region 221 and the outer suspended region 222 are capable of being excited by sound pressure to vibrate.

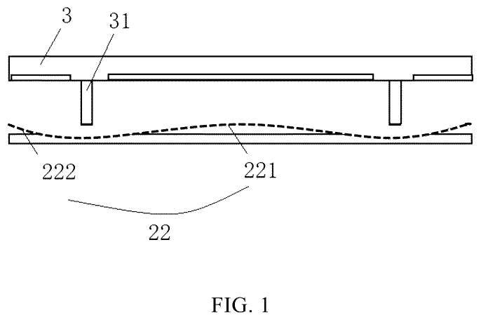

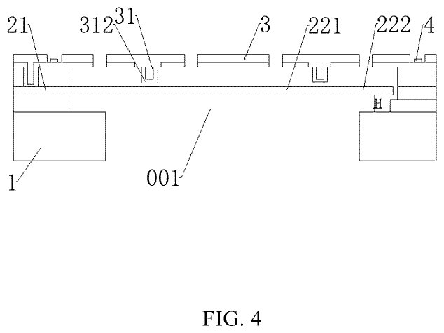

As shown in FIGS. 1 and 4, the substrate 1 forms an acoustic cavity 001 for accommodating structures for transmitting sound. The diaphragm 2 may be divided into the fixed part 21 and the suspended part 22 based on its connection to the substrate 1; wherein the fixed part 21 is fixed to the substrate 1, while the suspended part 22 is located over the acoustic cavity 001. That is to say, the fixed part 21 is centrally located and can vibrate; the fixed part 21 is located around it and cannot vibrate.

In one form, an edge region of the diaphragm 2 which is a part thereof serves as the fixed part 21, while the rest of the entire diaphragm 2 serves as the suspended part 22. The region of the suspended part 22 distal to the fixed part 21 may be laid on the substrate 1 or on the edge of the acoustic cavity 001.

The backplate 3 is provided on the substrate 1 and is opposite to the diaphragm 2. The backplate 3 and diaphragm 2 form a gap between them, and they constitute a capacitor together with the gap.

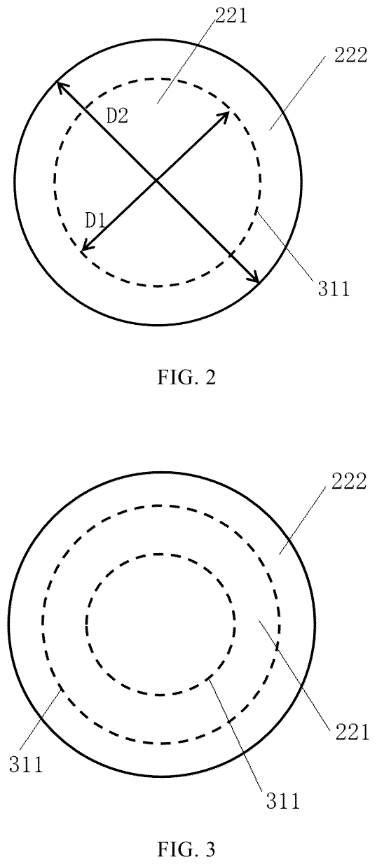

As shown in FIG. 2, the backplate 3 is provided with the support 31 distributed annularly thereon. The support 31 may be protrusions 311 formed on the backplate 3. The support 31 extends toward the diaphragm 2 and corresponds to a position of the suspended part 22. As shown in FIG. 2, the support 31 does not surround the suspended part 22; rather, it is distributed within the internal region of the suspended part 22 when viewed from a projection perspective. The support 31 divides the suspended part 22 into an inner suspended region 221 and an outer suspended region 222. According to the annular distribution of the support 31, along the radial direction of the diaphragm 2, a part of the suspended part 22 surrounded by the support 31 is the inner suspended region 221, and a part of the suspended part 22 outside the support 31 is the outer suspended region 222. Under the simple supporting effect of the support 31, the inner suspension region 221 and the outer suspended region 222 may vibrate in response to the vibration of sound and air respectively.

Optionally, a difference between mechanical sensitivity of the inner suspended region 221 and that of the outer suspended region 222 is less than or equal to 15%. When the mechanical sensitivity the inner and outer suspended regions conforms to the aforementioned characteristics, the vibratory effect expressed by the diaphragm in the MEMS microphone may make the electrical signals generated by the diaphragm 2 basically consistent, and the two are relatively matched. By using the two electrical signals in the inner and outer suspended regions as sound signals or by combining the two as differential signals, it is possible to improve the acoustic effect as a whole. Preferably, the difference in mechanical sensitivity Sm is less than 10%, close to 5% and below 5%, such that the absolute values of the mechanical sensitivity Sm are the same. In this way, when the two electrical signals in the inner and outer suspended regions are used as differential capacitors and differential signals, it is possible to ensure the higher accuracy, and is less likely to cause distortion in sound signals.

Optionally, a difference between critical voltages Vp of the inner suspended region 221 and the outer suspended region 222 may be less than or equal to 15%. By controlling the applied bias voltage and potential, and by controlling the dimensions of the inner suspended region 221 and the outer suspended region 222, it is possible to minimize their difference in critical voltages Vp, and the two are relatively matched. When the critical voltages Vp of the inner and outer suspended regions conform to the above numerical range, they are more likely to exhibit similar or the same mechanical performance so as to ensure high consistency in the vibratory behavior of the diaphragm, thereby improving the acoustic performance. Preferably, the difference in critical voltages Vp is less than 10%, close to 7% or below 7%, such that the absolute values of the critical voltages Vp are the same. In this way, especially in the technical solution using the differential capacitors, it is possible to reduce the error of the two electrical signals and prevent abnormal distortion.

Optionally, the annularly distributed support 31 is intended to divide the diaphragm 2 into the inner suspended region 221 and the outer suspended region 222. In the present disclosure, the annularly distributed support 31 may be arranged in a circular, rectangular, or elliptical pattern. Furthermore, for the structure of the support 31 itself, one can choose a combination of multiple protrusions to form the annularly distributed structure, or one can choose a substantially complete annular protrusion 311.

When sound pressure acts on the diaphragm 2, the diaphragm 2 vibrates as a result, thereby changing the capacitance between the diaphragm 2 and the backplate 3. Wherein, the gap between the backplate 3 and the diaphragm 2 may be an air gap or a gap composed of other media.

In the case where at least one of the backplate 3 and the diaphragm 2 is subjected to a bias voltage, or both the backplate 3 and the diaphragm 2 are subjected to a potential, the suspended part 22 may be pushed toward the backplate 3 under electromagnetic force so as to form an abutment with the support 31, and the support 31 supports the diaphragm 2. Moreover, both the inner suspended region 221 and the outer suspended region 222 can be excited by the sound pressure to produce mechanical vibration and change the output voltage of the capacitor, such that the electronic device employing it converts a sound signal into an electrical signal.

The simple support 31 in the prior art is located at the edge of the diaphragm 2. Due to the high mechanical sensitivity of the free diaphragm 2, its resonance frequency will drop to a lower level after it is designed into a diaphragm 2 with a larger size, which does not meet the performance demands of MEMS microphones. However, if the diaphragm 2 is of a relatively small area, its signal-to-noise ratio will be somehow limited and cannot improve the signal-to-noise ratio. In the present solution, the support 31 is located between the edge of the diaphragm 2 and the center of the diaphragm 2. Compared with the simply supported diaphragm 2 in the prior art, the present solution moves the support 31 inward toward the center of the diaphragm 2, which greatly increases the hardness of the inner suspended region 221 and the outer suspended region 222, and ensures sufficient mechanical strength. In actual operation, the resonant frequencies of both the inner suspended region 221 and the outer suspended region 222 are raised, and the diaphragm 2 as a whole has a wider frequency response capability and range. By adopting the MEMS microphone with this structure, on the premise of ensuring enough frequency bandwidth, it is also possible to enlarge the area of the diaphragm 2 so as to reduce the noise, improve the overall signal-to-noise ratio and improve the performance of the product. Wherein, the signal-to-noise ratio (SNR) refers to the ratio of signal to noise in an electronic device or system. Generally speaking, the larger the signal-to-noise ratio is, the less the noise mixed in the signal is and the higher the sound quality of the sound playback is, and vice versa.

A technical effect of the embodiment of the present disclosure is that by creatively providing the support 31 to divide the diaphragm 2 into the inner suspended region 221 and the outer suspended region 222 so as to improve the relative hardness of the inner suspended region 221 located inside the support 31, it is thus possible to increase area of the diaphragm 2 while ensuring frequency bandwidth of the product, reducing noise, and improving the signal-to-noise ratio, thus enhancing the overall performance of the microphone product.

Optionally, the support 31 is a continuous annular structure; or, the support 31 comprises a plurality of protrusions 311 distributed at intervals. In the present embodiment, the support 31 may be a continuous structure or a non-continuous structure. A continuous structure may be a circular, rectangular, or other annular structure; and a non-continuous structure may be a plurality of protrusions 311 distributed at intervals. According to actual design or production needs, the plurality of protrusions 311 may be distributed evenly or unevenly. With the support function of the support 31, it is possible to significantly increase the hardness of the inner suspended region 221 and the outer suspended region 222, and improve the resonant frequency. By using the continuous annular structure as the support 31, it is possible to relatively increase the hardness of the suspended region more significantly, especially such that the resonance frequency of the inner suspended region 221 rises more significantly. By using the support 31 formed by the plurality of discontinuous protrusions 311, it is possible to better improve the overall vibration consistency of the suspended part 22. Moreover, when the suspended part 22 is impacted by a strong air flow, the support 31 may somehow help the suspended part 22 to release the air pressure, thereby reducing the risk of damage to the diaphragm 2.

Optionally, in the embodiment shown in FIG. 2, the support 31 comprises a plurality of protrusions 311, which are centrally symmetrically distributed with respect to a center of the suspended part 22.

In the present embodiment, considering the stability and processing difficulty of the support 31, the plurality of protrusions 311 are provided to be centrally symmetrically distributed with respect to the center of the suspended part 22, which also makes the mechanical vibration of the diaphragm 2 more uniform and consistent.

Optionally, the support 31 may form not only an annular structure in one circle, but also an annular structure in two circles so as to divide the suspended part 22 into three regions. As shown in FIG. 3, this implementation may adopt a diaphragm 2 with a larger size. This design may further increase the size of the diaphragm 2 on the one hand, and thus reduce acoustic impedance of the noise and improve the signal-to-noise ratio. The additional annular structure of one circle may keep sufficient rigidity of the suspended part 22 to meet the demands of the resonance frequency and the frequency response bandwidth. Wherein, the number of support 31 may be increased by using the plurality of supports 31 in the continuous structure, which are centrally symmetrically distributed with respect to the center of the suspended part 22, i.e., coaxially provided: alternatively, by increasing the number of protrusions 311, and increasing the density of the plurality of protrusions 311 that are centrally symmetrically distributed with respect to the center of the suspended part 22.

The following takes the technical solution of the support 31 forming the annular structure of one circle as an example to illustrate the specific features that may be adopted in this solution.

Optionally, the inner suspended region 221 and the outer suspended region 222 of the suspended part 22 have a radial dimension ratio ranging from 0.6 to 0.8.

In the present embodiment, the suspended part 22 may be circular, rectangular, or other irregular shapes; the outer suspended region 222 may be circular, rectangular, or other irregular shapes; the inner suspended region 221 may be circular, rectangular, or other irregular shapes. When it is circular, its radial dimension is its diameter; when it is rectangular, its radial dimension is the length of its longer side; when it is of other irregular shapes, the radial dimension is the maximum length within it.

The inner suspended region 221 and the outer suspended region 222 may both be subjected to a bias voltage to form a capacitor with the backplate 3. By optimizing the radial dimensions of the inner suspended region 221 and the outer suspended region 22, the inner suspended region 221 and the outer suspended region 222 have similar or identical mechanical sensitivity (Sm) and critical voltage (Vp). In this way, during operation, the bias voltage between the back electrode of the backplate 3 (the back electrodes of the inner and outer suspended regions 222 may be interconnected) and the diaphragm 2 may ensure consistent displacement of the inner suspended region 221 and the outer suspended region 222, and the sound pressure signal acting on the entire diaphragm 2 also ensures consistent displacement of the inner suspended region 221 and the outer suspended region 222 such that the electrical signal (Vout=w/Gap*VB) is kept consistent, so as to reduce the acoustic resistance and its associated noise while enlarging the diaphragm 2, to reduce the loss of mechanical sensitivity due to parasitic capacitance (Cp) since the effective capacitance (Cm) is increased, to enhance the mechanical sensitivity Sm=(Sm·VB/Gap)·[Cm/(Cm+Cp)], and thus to improve the signal-to-noise ratio (SNR), thereby enhancing the overall performance of the MEMS microphone.

Optionally, the inner suspended region 221 and the outer suspended region 222 are circular in shape, and the radial dimensions thereof are diameters.

As shown in FIG. 2, the diameter of the inner suspended region 221 is D1, and the diameter of the outer suspended region 222 is D2. In this solution, the diameter of the inner suspended region 221 may range from 450 μm to 750 μm, and the diameter of the outer suspended region 222 may range from 650 μm to 1100 μm. The thickness of the diaphragm 2 ranges from 0.75 μm to 1.25 μm. By providing the above support 31 between the edge of the diaphragm 2 and the center of the diaphragm 2, it is possible to enlarge the radial dimension of the outer suspension region 222 accordingly while ensuring the mechanical strength of the diaphragm 2. That is to say, it is possible to enlarge the area of the diaphragm 2, reduce the acoustic resistance noise, and improve the signal-to-noise ratio, thereby improving the overall performance of the MEMS microphone.

Optionally, the inner suspended region 221 has a diameter of 500 μm: the outer suspended region 222 has a diameter of 750 μm; and the diaphragm 2 has a thickness of 1 μm.

Optionally, the mechanical sensitivity Sm of the inner suspended region 221 ranges from 2 nm/Pa to 9 nm/Pa. For example, the mechanical sensitivity Sm of the inner suspended region 221 is 2.25 nm/Pa.

In the present embodiment, the diameter of the inner suspended region 221 is preferably 500 μm or 700 μm, which may reduce the acoustic resistance noise and improve the signal-to-noise ratio by enlarging the area of the diaphragm 2 while ensuring that the diaphragm 2 has sufficient mechanical strength. For example, if the radial dimension of the inner suspended region 221 is 500 μm, the radial dimension of the outer suspended region 222 may be 750 μm. At this time, the mechanical sensitivity Sm of the inner suspended region 221 is approximately 2 nm/Pa to 3 nm/Pa, the size of the whole diaphragm also becomes larger, the sound noise may be reduced by 3 dB accordingly, and the resonant frequency fres of the diaphragm 2 itself is about 73 kHz.

Optionally, the radial dimension of the inner suspended region 221 is 700 μm, and the radial dimension of the outer suspended region 222 may be 900 μm. At this time, the mechanical sensitivity Sm of the inner suspended region 221 is approximately 9 nm/Pa, the size of the whole diaphragm also becomes larger, the sound noise may be reduced by 5 dB accordingly, and the resonant frequency fres of the diaphragm 2 itself is about 37 kHz.

The size design of the above two kinds of suspended part 22 may enable the sound resonance frequency of the suspended part 22 to reach more than 30 kHz in the actual operation, so as to achieve sufficient acoustic performance by using the free diaphragm 2 of the simple support form.

Optionally, the support 31 is formed with a reinforcing layer 312. In actual operation, the support 31 needs to withstand the impact generated by the deformation of the diaphragm 2. In the present embodiment, by providing the reinforcing layer 312 on the support 31, it is possible to enhance the mechanical strength of the support 31. The reinforcing layer 312 may improve the overall consistency of the acoustic performance of the MEMS microphone and avoids changes in acoustic performance due to deformation or damage of the support 31.

Optionally, the reinforcing layer 312 may be made of polysilicon. During the actual manufacture, a layer of polysilicon may be provided on the backplate 3 to form an electrically charged base board. The deposition process of polysilicon usually uses LPCVD, which provides better structural strength and hardness. Therefore, in this solution, a reinforcing layer 312 may be formed on the surface of the support 31 using the process of forming a polysilicon layer, for coming into contact with the suspended part 22 of the diaphragm 2.

Particularly, in the technical solution where polysilicon is used as the reinforcing layer 312 and the backplate 3 is also realized using a polysilicon layer to achieve electrification, to avoid the capacitor failure caused by the electrical conduction between the polysilicon reinforcement layer 312 and the diaphragm 2, optionally, the polysilicon layer on the support 31 is isolated from the polysilicon layer on the surface and/or inside the backplate 3. This isolation may be directly achieved through physical isolation, for example, by etching to eliminate the position of the polysilicon layer on the support 31 near the backplate 3. Subsequently, insulating materials such as silicon nitride and silicon oxide may be further deposited in the trenches.

Optionally, when the backplate 3 and/or the diaphragm 2 is energized, the suspended part 22 is spaced apart from the substrate 1 by at least 2 μm in the vibration direction of the suspended part 22.

In the present embodiment, when either the backplate 3 or the diaphragm 2 is energized, or when both the backplate 3 and the diaphragm 2 are energized, the suspended part 22 may produce mechanical vibration under sound pressure, so as to ensure that the suspended part 22 always maintains a separation of at least 2 μm (i.e., the H indicated in FIG. 4) from the substrate 1 in the vibration direction of the suspended part 22, which gives the diaphragm 2 sufficient vibration space, improves the mechanical sensitivity of the diaphragm 2, enhances its range of response to sound, and also improves the overall performance of the MEMS microphone.

Preferably, in the technical solution as shown in FIG. 4, the acoustic cavity 001 formed by the substrate 1 is under the inner suspended region 221, and the substrate 1 is under the outer suspended region 222. The substrate 1 somehow influences the vibration behavior of the outer suspended region 222. If the substrate 1 is close to the outer suspended region 222, the outer suspended region 222 will be subjected to air resistance during vibration, and cannot produce desirable vibration response to the vibration of the sound. Preferably, a space of no less than 2 μm is left between the diaphragm 2 and the substrate 1 so as to improve the vibration representation of the outer suspended region 222.

In the technical solution, the support 31 may also be provided on the substrate 1, as long as the support 31 can buttress and support the diaphragm 2 in such a way that it is divided into the inner suspended region 221 and the outer suspended region 222. By adjusting the position of the support 31 relative to the suspended part 22 of the diaphragm 2, it is possible that the inner suspended region 221 and the outer suspended region 222 form the mechanical sensitivity Sm and the critical voltage Vp which are matched correspondingly and are substantially identical, and thus the inner suspended region 221 and the outer suspended region 222 may be used together for acousto-electric conversion, resulting in a substantially consistent sound signal representation. The support 31 may also be divided into discrete support points, and for the solution of applying the suspended part 22 of the diaphragm in the shape of a rectangle, a square, or the like, the support 31 does not have to form a ring-shaped structure.

According to another aspect of the present disclosure, a microphone unit is provided. The microphone unit comprises a housing, a chip, and a MEMS microphone as described above, both the chip and the MEMS microphone are located within the housing, and the chip is electrically connected to the MEMS microphone.

In the present embodiment, the microphone unit comprises the housing, the chip and the above MEMS microphone located inside the housing. The chip is electrically connected to the MEMS microphone for supplying power to the MEMS microphone, so that the capacitor may be formed inside the MEMS microphone.

According to yet another aspect of the present disclosure, an electronic device is provided. The electronic device comprises a MEMS microphone as described above, which is provided to convert sound signals into electrical signals during operation.

In the present embodiment, when the electronic device is operating, the internal microphone unit may receive sound signals from the user and complete the conversion from the sound signals into the electrical signals. The electronic device may be a mobile phone, television, computer, smartwatch, and so on.

Optionally, the MEMS microphone provided in this solution may be prepared by a semiconductor vapor deposition method. The preparation method may mainly comprise the following steps:

Firstly, silicon is used as the substrate 1, and a layer of silicon dioxide is deposited on the substrate 1, followed by selective masking and etching. Secondly, the first low-stress polycrystalline silicon is deposited, doped, and annealed to obtain the diaphragm 2. Thirdly, a sacrificial layer is deposited on the diaphragm 2, and may be low-temperature deposited silicon oxide, silicon nitride, etc. And, trenches are formed by etching the sacrificial layer for further deposition of materials. Fourthly, a polycrystalline silicon layer is deposited on the sacrificial layer through a high-temperature deposition process. A portion of the polycrystalline silicon layer may serve as the conductive area of the backplate 3, and the polycrystalline silicon layer deposited in the trenches of the sacrificial layer located at the edge of the diaphragm 2 may be used as a conductive point for connecting the diaphragm 2 and the backplate 3 to different electrodes, respectively, while the polycrystalline silicon layer deposited in the trenches of the sacrificial layer located in the central region (the suspended part 22) of the diaphragm 2 may be used as the reinforcing layer 312 of the support 31.

Through the etching process, the polycrystalline silicon layer used for electrical connection, for the reinforcing layer 312, and for the backplate 3 cannot be electrically conducted, so as to prevent the reinforcing layer 312 and the diaphragm 2 from being short-circuited, to prevent the back plate 3 and the diaphragm 2 from being short-circuited, and the like.

Fifthly, further deposition on the polycrystalline silicon layer is used to form the structural layer of the backplate 3, which may be formed using a low-temperature silicon nitride deposition process. That is, the backplate 3 may be formed with a combined layered structure of silicon nitride and polycrystalline silicon.

Sixthly, further trenches are etched on material of the backplate 3 and materials such as chromium, nickel, and aluminum are deposited in them to act as welding points 4. Optionally, two welding points 4 may be provided above the material of the backplate 3, and may be respectively used to electrically connect to the diaphragm 2 and the backplate 3. In other implementations, more welding points 4 may be deposited to connect to different regions of the backplate 3 or the diaphragm 2.

The above embodiments focus on the differences between the various embodiments, and the different optimization features between the various embodiments, as long as they do not contradict each other, may be combined to form a better embodiment, which will not be repeated herein taking into account the brevity of the text.

Although some specific embodiments of the present disclosure have been described in detail through examples, those skilled in the art should understand that the above examples are for illustration only and are not intended to limit the scope of the present disclosure. Those skilled in the art should understand that the above embodiments can be modified without departing from the scope and spirit of the present disclosure. The scope of the present disclosure is defined by the accompanying claims.

1. A MEMS (Micro-Electro-Mechanical System) microphone, comprising:
a substrate, on which an acoustic cavity is formed;
a diaphragm having a fixed part which is fixed on the substrate, and a suspended part which is located above the acoustic cavity;
a backplate provided on the substrate, with a gap formed between the backplate and the diaphragm and provided with a support distributed annularly thereon, the support extending toward the diaphragm, corresponding to a position of the suspended part and dividing the suspended part into an inner suspended region and an outer suspended region, and the inner suspended region having a mechanical sensitivity and a critical voltage that are correspondingly matched to those of the outer suspended region;
wherein when the backplate and/or the diaphragm is energized, the suspended part is configured to abut against the support such that both the inner suspended region and the outer suspended region are excited by sound pressure to vibrate.

2. The MEMS microphone according to claim 1, wherein a mechanical sensitivity difference between of the inner suspended region and that of the outer suspended region is less than or equal to 15%; and
a critical voltage difference between the inner suspended region and the outer suspended region is less than or equal to 15%.

3. The MEMS microphone according to claim 1, wherein the support comprises a continuous annular structure; or
the support comprises a plurality of protrusions distributed at intervals.

4. The MEMS microphone according to claim 1, wherein the support comprises a plurality of protrusions, which are centrally symmetrically distributed with respect to a center of the suspended part.

5. The MEMS microphone according to claim 1, wherein the inner suspended region and the outer suspended region of the suspended part have a radial dimension ratio ranging from 0.6 to 0.8.

6. The MEMS microphone according to claim 1, wherein the inner suspended region and the outer suspended region are circular in shape with radial dimensions being diameters.

7. The MEMS microphone according to claim 1, wherein the inner suspended region has a diameter ranging from 450 μm to 750 μm;
the outer suspended region has a diameter ranging from 650 μm to 1100 μm; and
the diaphragm has a thickness ranging from 0.75 μm to 1.25 μm.

8. The MEMS microphone according to claim 1, wherein the inner suspended region has a diameter of 500 μm;
the outer suspended region has a diameter of 750 μm; and the diaphragm has a thickness of 1 μm.

9. The MEMS microphone according to claim 1, wherein the support is formed with a reinforcing layer thereon.

10. The MEMS microphone according to claim 9, wherein the reinforcing layer comprises polycrystalline silicon.

11. The MEMS microphone according to claim 1, wherein when the backplate and/or the diaphragm is energized, the suspended part is spaced apart from the substrate by at least 2 μm in a vibration direction of the suspended part.

12. A MEMS microphone, comprising:
a substrate, on which an acoustic cavity is formed;
a diaphragm provided on the substrate and located above the acoustic cavity;
a backplate provided on the substrate with a gap formed between the backplate and the diaphragm; and
a support provided on the substrate and/or the backplate, the support being configured for supporting the diaphragm to divide the diaphragm into an inner suspended region and an outer suspended region, and the inner suspended region having a mechanical sensitivity and a critical voltage that are correspondingly matched to those of the outer suspended region.

13. An electronic device, comprising a MEMS microphone according to claim 1, wherein the MEMS microphone is configured for converting a sound signal into an electrical signal in operation.
